(19) United States
(12) Patent Application Publication
(10) Pub. No.: US 2009/0040732 A1
(43) Pub. Date: Feb. 12, 2009

(54) PRINTED CIRCUIT BOARD STRUCTURE FOR HEAT DISSIPATION

(76) Inventors: Ro-Bin Yang, Changhua County (TW); Yi-Hong Shen, Nantou County (TW)

Correspondence Address: NORTH AMERICA INTELLECTUAL PROPERTY CORPORATION, P.O. BOX 506, MERRIFIELD, VA, 22116, US

(21) Appl. No.: 11/834,652

(22) Filed: Aug. 6, 2007

(51) Int. Cl. H05K 7/20

(52) U.S. Cl. 361/718

(57) ABSTRACT

A printed circuit board structure for heat dissipation of an integrated circuit includes a printed circuit board having an opening, and a thermal conductive material disposed within the opening, wherein the integrated circuit is disposed over the opening and the thermal conductive material is thermally connected to the integrated circuit. The opening can be designed to have a specific shape to allow the opening to be completely filled by the thermal conductive material during a fillet process, therefore obtaining better heat dissipation performance and protecting the integrated circuit from over heating.

### BACKGROUND OF THE INVENTION

1. Field of the Invention

The present invention relates to a printed circuit board structure, and more particularly, to a printed circuit board structure for dissipating heat from an integrated circuit.

2. Description of the Prior Art

In order to help dissipating heat from an integrated circuit generated during operation, a conventional printed circuit board is designed to have a structure shown in FIG. 1—a plurality of vias 110 penetrating through the printed circuit board 100 are formed in a predetermined area 120 reserved for placing the integrated circuit. Because the vias 110 are hollow and through the printed circuit board 100, the heat generated from the integrated circuit can be conducted to the inner layer and the bottom layer of the printed circuit board 100 through the vias 110. However, when an integrated circuit generating a lot of heat (such as a pulse width modulation integrated circuit embedded with a MOSFET) is applied to the printed circuit board structure of FIG. 1, the vias 110 are not able to dissipate such a great amount of heat. Therefore, the temperature of the integrated circuit may exceed the thermal protection threshold and cause the integrated circuit to shut down, influencing the operation of the overall system.

### SUMMARY OF THE INVENTION

One objective of the present invention is therefore to provide a printed circuit board structure which can efficiently dissipate great amounts of heat generated by an integrated circuit to protect the integrated circuit from overheating.

According to an exemplary embodiment of the present invention, a printed circuit board structure for carrying an integrated circuit is disclosed. The printed circuit board structure comprises a printed circuit board having an opening, and a thermal conductive material disposed within the opening; wherein the integrated circuit is disposed over the opening and the thermal conductive material is thermally connected to the integrated circuit.

According to another exemplary embodiment of the present invention, an electronic device is disclosed. The electronic device comprises a housing having at least one side wall, a printed circuit board having an opening disposed within the housing, a first thermal conductive material disposed within the opening, and a second thermal conductive material disposed between the first thermal conductive material and the at lease one sidewall, wherein the integrated circuit is disposed over the opening and the first thermal conductive material is thermally connected to the integrated circuit and the second thermal material.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a cross-sectional diagram of a conventional printed circuit board having a plurality of vias for heat dissipation.

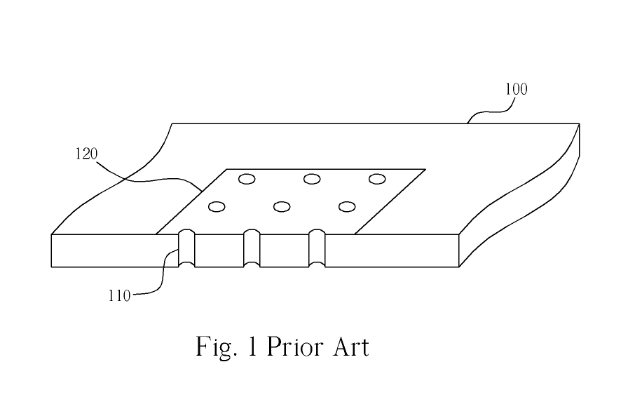

FIG. 2 is a diagram of a printed circuit board having an opening according to an exemplary embodiment of the present invention.

FIG. 3 is a cross-sectional diagram of a printed circuit board structure comprising the printed circuit board shown in FIG. 2 according to an exemplary embodiment of the present invention.

FIG. 4 is a top-view diagram of a printed circuit board structure having a specific opening according to another exemplary embodiment of the present invention.

FIG. 5 is an upward-view diagram of the printed circuit board structure in FIG. 3.

FIG. 6 is a cross-sectional diagram of a printed circuit board structure according to another exemplary embodiment of the present invention.

### DETAILED DESCRIPTION

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”.

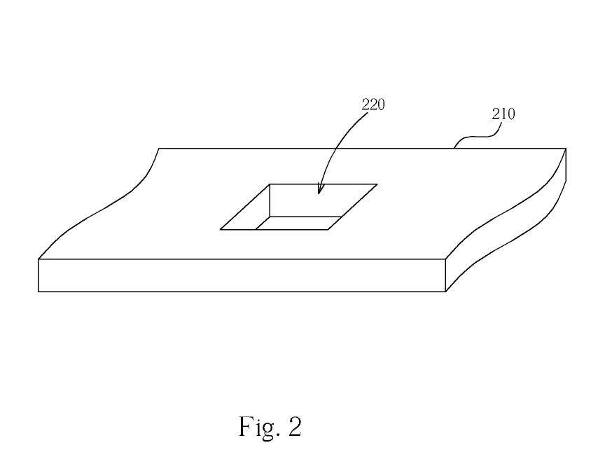

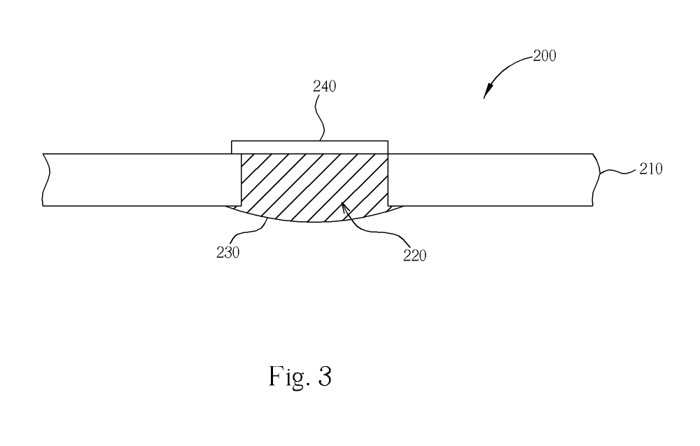

Please refer to FIG. 2 in conjunction with FIG. 3. FIG. 2 is a diagram of a printed circuit board 210 having an opening 220 according to an exemplary embodiment of the present invention, and FIG. 3 is a cross-sectional diagram of a printed circuit board structure 200 comprising the printed circuit board 210 according to an exemplary embodiment of the present invention. The printed circuit board structure 200 comprises the printed circuit board having the opening 220, located at a predetermined position of an integrated circuit 240. In order to increase the heat radiating area and heat radiating route of the printed circuit board structure 200, thermal conductive material 230 is disposed within the opening 220 (a preferred embodiment is that the opening 220 is filled with the thermal conductive material 230). The thermal conductive material 230 can be metal (e.g. tin), solder paste or other material that conducts heat. An integrated circuit 240 is disposed on a first side of the thermal conductive material 230 by thermally connecting a thermal pad (not shown) of the integrated circuit 240 to the thermal conductive material 230. In this way, the heat generated by the integrated circuit 240 when operating can be effectively conducted to the inner layer and the bottom layer of the printed circuit board 210 through the thermal pad of the integrated circuit 240 and the thermal conductive material 230. Because the size of the opening 220 is larger than the vias 110 of the conventional printed circuit board 100, and the thermal conductive material 230 has a greater heat dissipation capability than that of vias 110, the printed circuit board structure 200 can help the integrated circuit 240 dissipate heat more rapidly. Moreover, the thermal conductive material 230 can further cover part of a second side of the printed circuit board 210 around the opening 220, as shown in FIG. 3, to enlarge the heat radiating area and the heat radiating route, bringing better heat dissipation performance. In this situation, nodes of the printed circuit board 210 positioned around the thermal conductive material 230 can be designed to have identical voltage level to prevent short circuits. In one embodiment, the thermal conductive material 230 is electrically connected to one pin of the integrated circuit 240 to act as an enlarged pin of the integrated circuit 240.

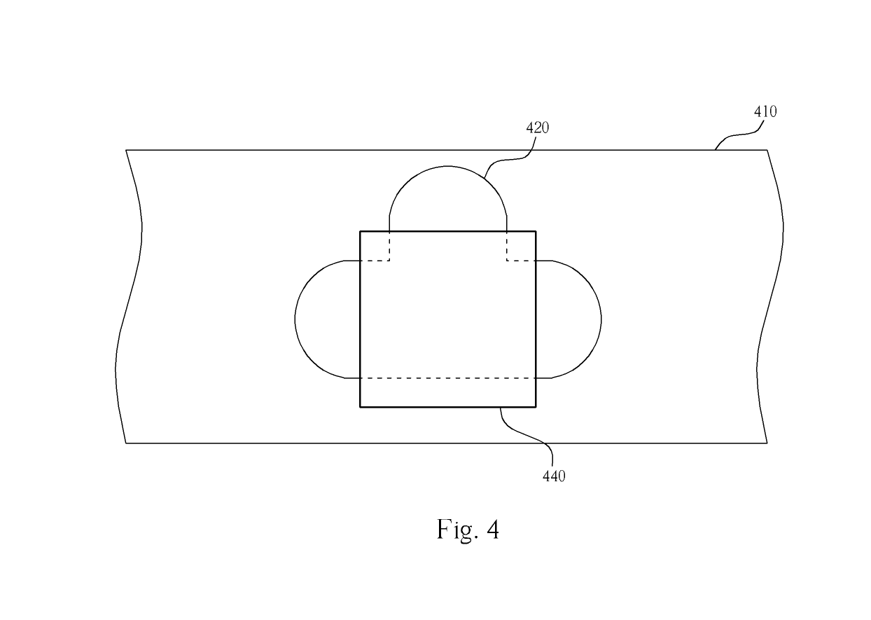

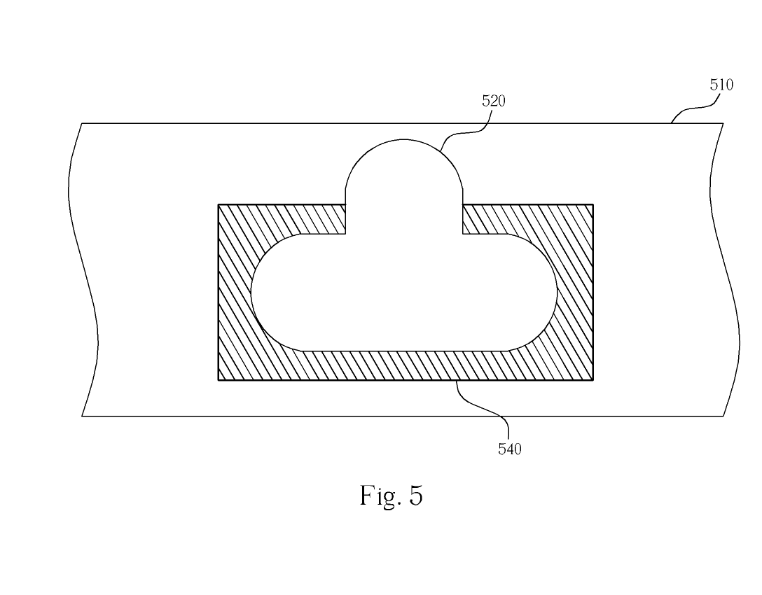

Note that although the opening 220 and the thermal conductive material 230 shown in FIG. 3 are formed exactly below the integrated circuit 240, it is not meant to be a limitation of the present invention. The area of the opening 220 need not necessarily be the same as the area of the integrated circuit 240, and the integrated circuit 240 may cover only part of the opening 220 and the thermal conductive material 230. Please refer to FIG. 4, which is a top-view diagram of a printed circuit board 410. In fact, if the opening 420 is not completely covered by the integrated circuit 440 on the side of the printed circuit board 410 where the integrated circuit 440 is disposed, the thermal conductive material can be filled into the opening 420 more completely during solder fillet processing. This is because air existing inside the opening 420 before the thermal conductive material is filled in can be pushed out through the exposed part of the opening 420 outside the integrated circuit 440 during the solder fillet process, and therefore the opening 420 can be completely filled by the thermal conductive material, obtaining better heat dissipation performance. Note that the shape of the opening 420 is not limited to the ellipse type as shown in FIG. 4. Other shapes that benefit the solder fillet process to fill the thermal conductive material into the opening 420 can also be adopted in the present invention. Moreover, referring to FIG. 5, a solder mask 540 can be further disposed around the opening 520 on the second side of the printed circuit board 510 to isolate the opening 520 from other nodes of the printed circuit board 510. Since forming the solder mask 540 on the printed circuit board 510 is a well-known skill that helps the solder fillet process fill the thermal conductive material, detailed description is omitted for brevity.

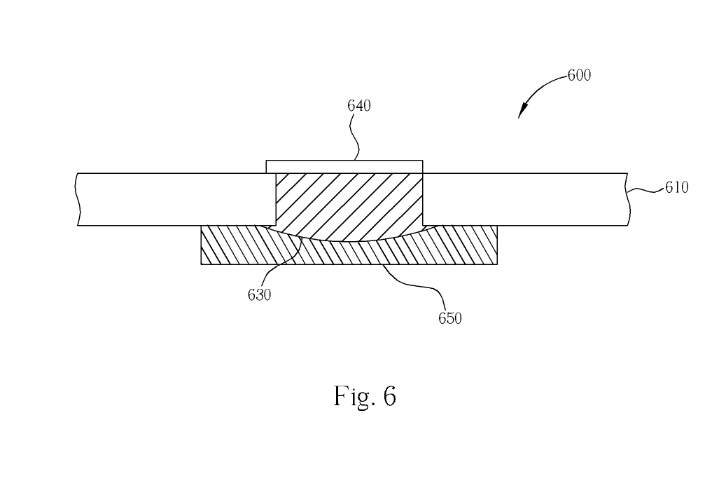

The printed circuit board structure 600 can further comprise a second thermal conductive material, such as the heat sink layer 650 shown in FIG. 6, disposed on the second side of the printed circuit board 610 and thermally connected to the first thermal conductive material 630. The heat sink layer 650 has heat dissipation capability and is non-electrically-conductive; for example, it can be made of thermal adhesive, for connecting the first thermal conductive material 630 to an additional heat-dissipating device (not shown) such as a case, cooler, or connecting the first thermal conductive material 630 to at least one side wall of a housing of an electronic device when the printed circuit board structure 600 is implemented in the electronic device. In another embodiment, the second thermal conductive material, such as the heat sink layer 650, is electrically conductive (for example, made of aluminum) and nodes of the printed circuit board 610 contacting with the heat sink layer 650 are designed to have an identical voltage level. Similarly, the size and the position of the heat sink layer 650 in FIG. 6 are for illustrative purposes only, and are not meant to be a limitation of the present invention. For example, the heat sink layer 650 does not need to cover whole thermal conductive material 630 if it can provide adequate heat dissipation function. It has been found that when the printed circuit board structure 600 is put in a 55° C. chamber, the temperature of the integrated circuit 640 does not exceed 104.2° C. during operation, which is about 11° C. lower than the temperature of the integrated circuit implemented with conventional printed circuit board structures. This provides that the printed circuit board structure 600 can effectively dissipate heat of the integrated circuit 640, and prevent the integrated circuit 640 from being over heated.

Those skilled in the art will readily observe that numerous modifications and alterations of the device and method may be made while retaining the teachings of the invention.

What is claimed is:

1. A printed circuit board structure for carrying an integrated circuit, comprising:
a printed circuit board having an opening; and
a thermal conductive material disposed within the opening,
wherein the integrated circuit is disposed over the opening and the thermal conductive material is thermally connected to the integrated circuit.

2. The printed circuit board structure of claim 1, wherein the integrated circuit is disposed on a first side of the printed circuit board, and the thermal conductive material further covers part of a second side of the printed circuit board around the opening.

3. The printed circuit board structure of claim 1, wherein the opening is not completely covered by the integrated circuit.

4. The printed circuit board structure of claim 1, wherein the thermal conductive material comprises metal.

5. The printed circuit board structure of claim 1, wherein the thermal conductive material comprises tin.

6. The printed circuit board structure of claim 1, wherein the integrated circuit is disposed on a first side of the printed circuit board, and the printed circuit board structure further comprises a heat sink layer disposed on a second side of the printed circuit board and thermally connected to the thermal conductive material.

7. The printed circuit board structure of claim 6, wherein the heat sink layer is non-electrically-conductive.

8. The printed circuit board structure of claim 6, wherein the heat sink layer is made of thermal adhesive, for thermally connecting the thermal conductive material to a heat-dissipating device.

9. The printed circuit board structure of claim 6, wherein the heat sink layer is electrically conductive, and nodes of the printed circuit board contacting with the heat sink layer are designed to have identical voltage levels.

10. The printed circuit board structure of claim 1, wherein nodes of the printed circuit board positioned around the thermal conductive material are designed to have identical voltage levels.

11. The printed circuit board structure of claim 1, wherein the integrated circuit is disposed on a first side of the printed circuit board, and the printed circuit board structure further comprises a solder mask disposed around the thermal conductive material on a second side of the printed circuit board.

12. The printed circuit board structure of claim 1, further comprising a thermal pad disposed between the integrated circuit and the thermal conductive material.

13. An electronic device, comprising:
a housing having at least one side wall;
a printed circuit board having an opening disposed within the housing;
a first thermal conductive material disposed within the opening; and
a second thermal conductive material disposed between the first thermal conductive material and the at lease one sidewall,
wherein the integrated circuit is disposed over the opening and the first thermal conductive material is thermally connected to the integrated circuit and the second thermal material.

14. The electronic device of claim 13, wherein the integrated circuit is disposed on a first side of the printed circuit board, and the first thermal conductive material further covers part of a second side of the printed circuit board around the opening.

15. The electronic device of claim 13, wherein the opening is not completely covered by the integrated circuit.

16. The electronic device of claim 13, wherein the first thermal conductive material comprises tin.

17. The electronic device of claim 13, wherein the second conductive material comprises thermal adhesive or aluminum.

18. The electronic device of claim 13, wherein the integrated circuit is disposed on a first side of the printed circuit board, and the printed circuit board structure further comprises a solder mask disposed around the first thermal conductive material on a second side of the printed circuit board.

19. The electronic device of claim 13, further comprising a thermal pad disposed between the integrated circuit and the first thermal conductive material.
